(19) United States
(12) Patent Application Publication
(10) Pub. No.: US 2006/0110849 A1
(43) Pub. Date: May 25, 2006

(54) Method for stacking BGA packages and structure from the same

(76) Inventors: Cheng-Yin Lee, Kaoshiung (TW); Wei-Chang Tai, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/210,700

(22) Filed: Aug. 25, 2005

(30) Foreign Application Priority Data
Oct. 28, 2004 (TW) 093132776

(51) Int. Cl. H01L 21/00

(52) U.S. Cl. 438/106; 257/686

(57) ABSTRACT

The present invention relates to a method for stacking BGA packages. At first, a first BGA package is provided. The first BGA package includes a first substrate, at least one first chip and a plurality of first connecting balls. The first substrate has a first upper surface and a first bottom surface. The first chip is disposed on the first upper surface. The first connecting balls are disposed on a plurality of first connecting pads of the first upper surface. Then, a second BGA package is provided. The second BGA package includes a second substrate, at least one second chip and a plurality of second connecting balls. The second substrate has a second upper surface and a second bottom surface. The second connecting balls are disposed on a plurality of second connecting pads of the second bottom surface. The second BGA package is stacked on the first BGA package for the second connecting balls to contact the corresponding first connecting balls. Then, the first connecting balls and the corresponding second connecting balls are reflowed into a plurality of integrated spacer balls. The spacer balls connect the first connecting pads and the second connecting pads for providing a stack gap.

### BACKGROUND OF THE INVENTION

1. Field of the Invention

The present invention relates to a method for stacking multi-packages, and more particularly to a method for stacking BGA packages for forming large spacer balls on small connecting pads and the structure from the same.

2. Description of the Related Art

The market demand for electronic products in the wireless industry drives the development and progress of the technologies in the wireless industry. For example, most of the mobile phones today are provided with multi-functions of color display screen, camera, MP3, etc. However, not every electronic product has such multi-functions or the same requirements. Accordingly, in order to assemble different products meeting the market demand in a short period, a plurality of chips of different functions are packaged into multiple semiconductor packages respectively and then stacked with each other to form a full function electronic module i.e., a System in Package (SIP). Therefore, the technology of stacking multiple semiconductor packages has gained growing attention. Multiple chips in the electronic module may be individually or randomly arranged in the semiconductor package, and after being tested, the chips are stacked, and thereby the technology of stacking multiple semiconductor packages avoids packing chips in an encapsulation at the same time, which results in a low yield.

Referring to FIGS. 1A to 1D, a method for stacking multiple semiconductor packages disclosed in the ROC Patent Publication No. 554509 “Multi-chip Packaging Structure” is shown. With reference to FIG. 1A, a first semiconductor package 110 is provided at first, which comprises a base substrate 111 and a first semiconductor chip 112. The base substrate 111 includes an upper surface 113 and a bottom surface 114, wherein the upper surface 113 is provided with a first set of connecting pads 115 and a second set of connecting pads 116, while the bottom surface 114 of the base substrate 111 is provided with a third set of connecting pads 117. The first semiconductor chip 112 is disposed on the upper surface 113 of the base substrate 111 and connected to the first set of connecting pads 115 by a plurality of connecting wires 118. An encapsulation 119 encapsulates the first semiconductor chip 112 and the connecting wire 118.

With reference to FIG. 1B, an intermediate substrate 120 is joined to the first semiconductor package 110. The intermediate substrate 120 has an upper surface 121, a bottom surface 122 and an opening 123 that accommodates the first semiconductor chip 112. The intermediate substrate 120 also has a first set of intermediate connecting pads 124 formed on the upper surface 121 and a second set of intermediate connecting pads 125 formed on the bottom surface 122. The intermediate substrate 120 is joined to the first semiconductor package 110 by a plurality of first solder balls 141. The first solder balls 141 are used to connect the second set of connecting pads 116 of the base substrate 111 to the second set of intermediate connecting pads 125 of the intermediate substrate 120.

With reference to FIGS. 1C and 1D, a second semiconductor package 130 and the intermediate substrate 120 are installed. The second semiconductor package 130 comprises a connecting substrate 131 and at least one second semiconductor chip 132. The connecting substrate 131 includes an upper surface 133 provided with a first set of connecting pads 135 and a bottom surface 134 provided with a second set of connecting pads 136. The second semiconductor chip 132 is disposed on the upper surface 133 and connected to the first set of connecting pads 135 through a plurality of connecting wires 137. An encapsulation 138 is used to encapsulate the second semiconductor chip 132 and the connecting wires 137. The second semiconductor package 130 is joined to the intermediate substrate 120 by a plurality of second solder balls 142. The second solder balls 142 connect the second set of connecting pads 136 of the second semiconductor package 130 to the first set of intermediate connecting pads 124 of the intermediate substrate 120. Finally, a plurality of solder balls 150 are formed on the third set of connecting pads 117 of the base substrate 111 so as to complete a stacking structure 100 of multiple semiconductor packages.

However, the intermediate substrate 120 increases the manufacturing cost of the stacking structure 100 of multiple semiconductor packages. Also, when the intermediate substrate 120 connects the first solder balls 141 and the second solder balls 142, the intermediate substrate 120 having an opening 123 is subjected to the pressure to become curled, which results in a bad electrical connection of the stacking structure 100 of multiple semiconductor packages.

Consequently, there is an existing need for a stacking package structure to solve the above-mentioned problems.

### SUMMARY OF THE INVENTION

The object of the present invention is to provide a method for stacking BGA packages. At first, a first BGA package is provided. The first BGA package includes a first substrate, at least one first chip and a plurality of first connecting balls. The first substrate has a first upper surface, a first bottom surface and includes a plurality of first connecting pads on the first upper surface. The first connecting balls are disposed on the first connecting pads. Then, a second BGA package is further provided. The second BGA package includes a second substrate, at least one second chip and a plurality of second connecting balls. The second substrate has a plurality of second connecting pads under the second bottom surface. The second connecting balls are disposed on the second connecting pads. The second BGA package is stacked on the first BGA package for the second connecting balls to contact the first connecting balls. The corresponding contacted first connecting balls and the second connecting balls are reflowed to be melted into a plurality of spacer balls. Both BGA packages may be connected to the spacer balls directly, without disposing an additional intermediate circuit board or carrying out other steps of connecting BGA packages by other electrical connection elements.

Another object of the present invention is to provide a structure stacked by multiple BGA packages, which comprises a first BGA package and a second BGA package. The first BGA package includes a first substrate, at least one first chip and a plurality of first connecting balls, in which the first substrate includes a first upper surface, a first bottom surface and a plurality of first connecting pads on the first upper surface. The first chip is disposed on the first upper surface of the first substrate. The first connecting balls are disposed on the first connecting pads. The second BGA package includes a second substrate, at least one second chip and a plurality of second connecting balls. The second substrate includes a second upper surface, a second bottom surface and a plurality of second connecting pads on the second bottom surface. The second connecting balls are disposed on the second connecting pads. Preferably, the first connecting balls are of the same dimension as the second connecting balls and formed on the first and second connecting pads of proper area. The first and second connecting balls contact each other correspondingly and are reflowed to be melted into a plurality of spacer balls, so as to electrically connect the first and second connecting pads. In other words, the melted spacer balls of large dimension may be used to connect the first and second connecting pads of small area; therefore, it is convenient for the first and second substrates to form more traces.

Still another object of the present invention is to provide a stackable BGA package structure. The first BGA package includes a first substrate, at least one first chip and a plurality of first connecting balls. The first chip is disposed on the first upper surface of the first substrate. The first connecting balls are disposed on a plurality of first connecting pads of the first upper surface. Preferably, the height of the first connecting balls is smaller than the heights of the first encapsulation or the first chip. Therefore the first BGA package can be inverted to prevent the first connecting balls of small dimension from colliding.

The method for stacking BGA packages according to the present invention comprises the following steps. First, providing a first BGA package comprising a first substrate, at least one first chip and a plurality of first connecting balls. The first substrate has a first upper surface, a first bottom surface and a plurality of first connecting pads on the first upper surface. The first chip is disposed on the first upper surface of the first substrate. The first connecting balls are disposed on the first connecting pads. Then, providing a second BGA package comprising a second substrate, at least one second chip and a plurality of second connecting balls. The second substrate has a second upper surface, a second bottom surface and a plurality of second connecting pads on the second upper surface. The second connecting balls are disposed on the second connecting pads. Then, stacking the second and first BGA packages so that the second connecting balls contact the first connecting balls of the first BGA package correspondingly. Then, reflowing the first and second connecting balls contacting each other correspondingly in order to melt them into a plurality of spacer balls connecting the first connecting pads of the first BGA package and the second connecting pads of the second BGA package.

### BRIEF DESCRIPTION OF THE DRAWINGS

FIGS. 1A to 1D are sectional views showing the conventional method for stacking multiple semiconductor packages disclosed in the ROC Patent Publication No. 554509; and

FIGS. 2A to 2D are sectional views showing the method for stacking BGA packages according to the present invention.

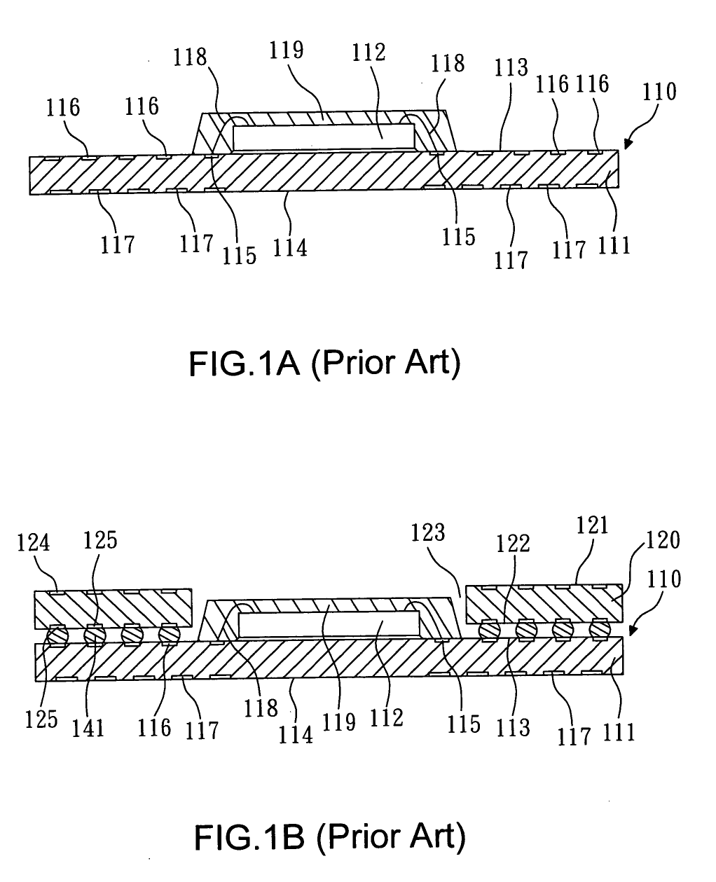

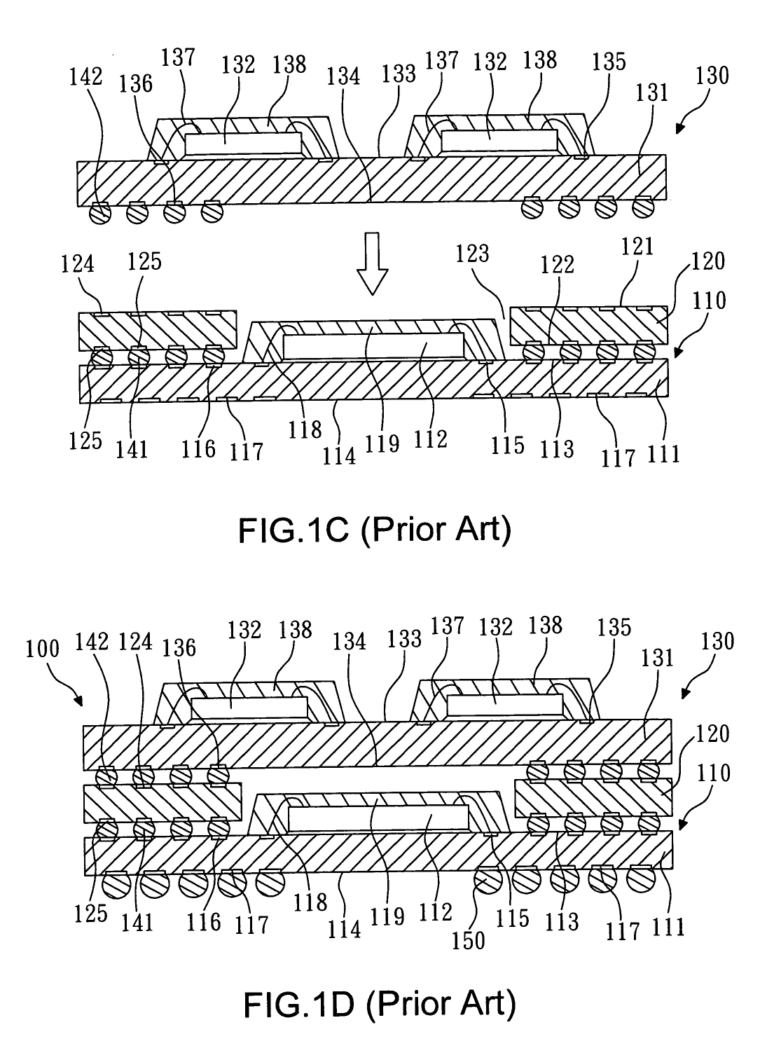

### DETAILED DESCRIPTION OF THE INVENTION

The present invention will be described by illustrating the following embodiments with reference to accompanying drawings.

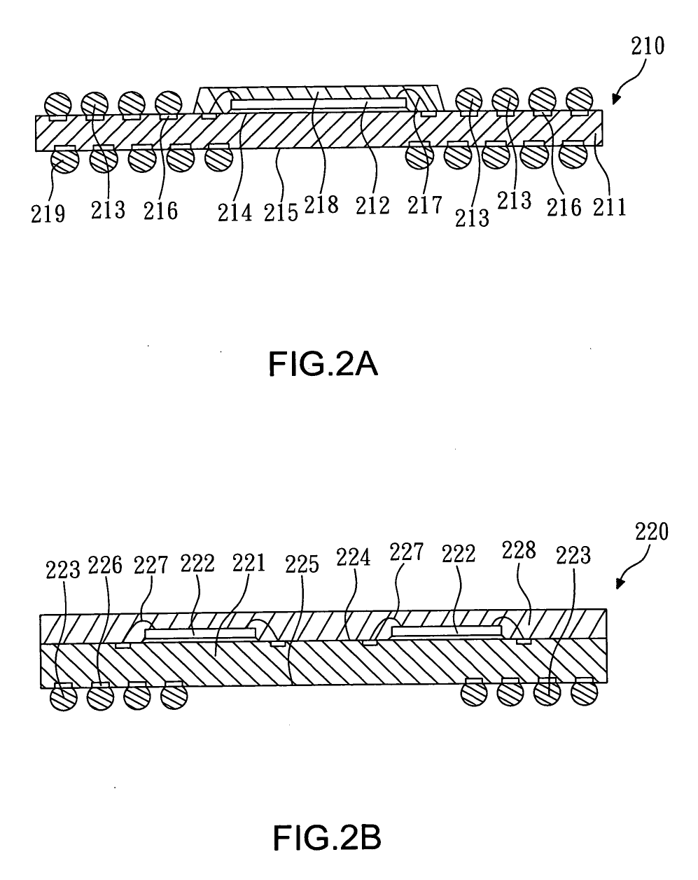

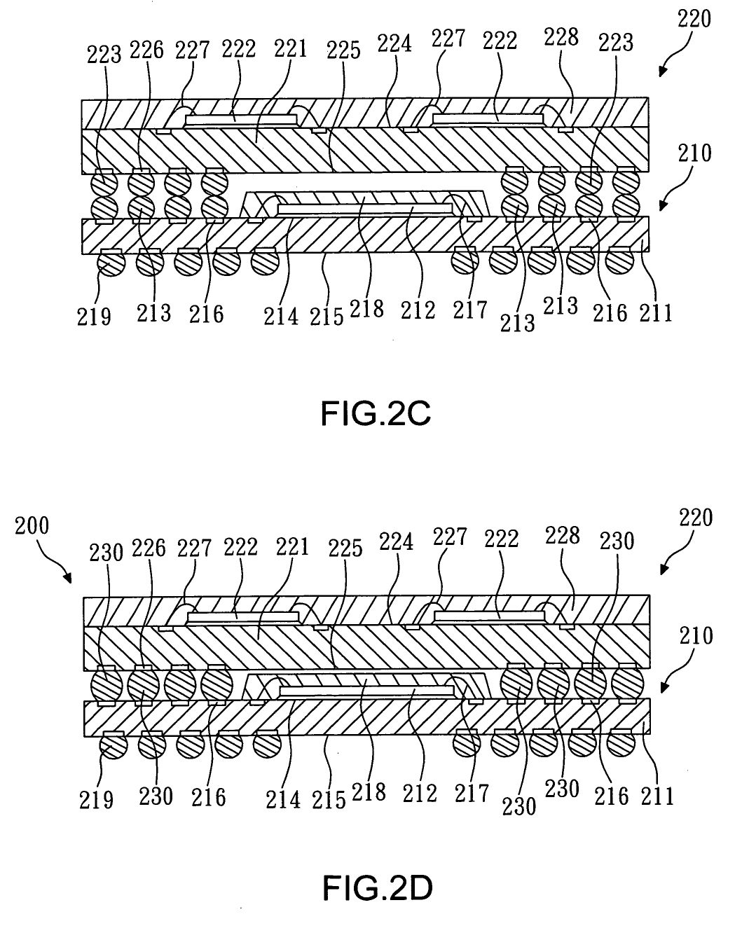

Referring to FIGS. 2A to 2D, a method for stacking BGA packages according to a preferred embodiment of the present invention is shown. Referring to FIG. 2A, a first BGA package 210 is provided. The first BGA package 210 comprises a first substrate 211, a first chip 212 and a plurality of first connecting balls 213. The first substrate 211 has an upper surface 214 and a bottom surface 215 and includes a plurality of first connecting pads 216 on the first upper surface 214. In this embodiment, the first connecting pads 216 are formed around the first upper surface 214. The first substrate 211 may be a multi-layered printed circuit board. The first chip 212 is disposed on the first upper surface 214 of the first substrate 211 and may be electrically connected to the first upper surface 214 by wire bonding or flip chipping. In this embodiment, a plurality of first connecting wires 217 are used for connecting the first chip 212 and the first substrate 211, and encapsulated with the first chip 212 by the first encapsulation 218. Alternatively, the first chip 212 may be joined to the first upper surface 214 of the first substrate 211 by flip chipping (not shown) so as to dispose the active face of the first chip 212 downward to the first substrate 211.

The first chip 212 may be an Application Specific Integrated Circuit (ASIC) chip. The first connecting balls 213 are disposed on the first connecting pads 216. In this embodiment, the first connecting balls 213 are around the first chip 212. The material of the first connecting balls 213 may be tin-lead alloy, tin or tin-copper alloy. Preferably, the height of the first encapsulation 218 or the first chip 212 is larger than that of the first connecting balls 213. The height of the first encapsulation 218 is 0.35 mm, while the height of the first connecting balls 213 is in the range of 0.28˜0.35 mm, and the first connecting balls 213 are formed on the first connecting pads 216 of proper area.

Referring to FIG. 2B, a second BGA package 220 is provided. The second BGA package 220 comprises a second substrate 221, at least one second chip 222 and a plurality of second connecting balls 223. The second substrate 221 has a second upper surface 224 and a second bottom surface 225 and includes a plurality of second connecting pads 226 on the second bottom surface 225. Preferably, the second connecting pads 226 are formed around the bottom surface 225, so as to correspond to the first connecting pads 216. In this embodiment, the second chips 222 are disposed on the second upper surface 224 of the second substrate 221. A plurality of second connecting wires 227 connect each of the second chips 222 to the second substrate 221 through wire bonding. A second encapsulation 228 is formed on the second upper surface 224 of the second substrate 221 and encapsulates the second chips 222 and the second connecting wires 227. The second chips 222 may be Flash Memory (FLASH) or Synchronous Dynamic Random Access Memory (SDRAM). The second connecting balls 223 are disposed on the second connecting pads 226. The material of the connecting balls may be lead-tin alloy, tin or tin-copper alloy. Preferably, the dimension of the second connecting ball 223 approximates to the dimension of the first connecting ball 213, and the area of the second connecting pad 226 approximates to the area of the first connecting pads 216. Typically, the second substrate 221 is a multi-layered printed circuit board having the same dimension as the first substrate 211.

Referring to FIG. 2C, the second BGA package 220 and the first BGA package 210 are stacked so that the second connecting balls 223 of the second BGA package 220 contact the first connecting balls 213 of the first BGA package 210 correspondingly. The total height of the first connecting balls 213 and the second connecting balls 223 contacting each other correspondingly and vertically is larger than the thickness of the first encapsulation 218. Furthermore, if the first chips 212 connect to the first substrate 211 by flip chipping (not shown), the total height of the first connecting balls 213 and the second connecting balls 223 contacting each other correspondingly is larger than the thickness of the first chip 212.

Referring to FIG. 2D, the first connecting balls 213 and the second connecting balls 223 contacting each other correspondingly are reflowed in order to be melted into a plurality of spacer balls 230. The spacer balls 230 connect the first connecting pads 216 of the first BGA package 210 and the second connecting pads 226 of the second BGA package 220. Preferably, the height of the first encapsulation 218 is smaller than or equal to that of the spacer balls 230. The height of the spacer balls 230 is in a range of 0.35˜0.5 mm, preferably 0.38 mm, and the space between the spacer balls 230 is 0.65 mm. Furthermore, a plurality of solder balls 219 may be formed on the first bottom surface 215 of the first substrate 211. In this embodiment, the solder ball 219 has the same dimension as the first connecting ball 213. The solder balls 219 are electrically connected to the first connecting balls 213 of the first upper surface 214 through a plurality of circuits (not shown) of the first substrate 211. The stacking structure 200 of the BGA package is completed through the above-mentioned process.

In the above-mentioned method for stacking BGA packages, the first connecting balls 213 and the second connecting balls 223 contacting each other correspondingly are reflowed to be melted to form the spacer balls 230 in order to electrically connect both of the BGA packages. In such process, an additional intermediate circuit board or other electrical connection elements are not required to connect both of the BGA packages. In the stacking structure 200 of the BGA package, the first connecting balls 213 and the second connecting balls 223 are of the same dimension. After they are reflowed to be melted into the large spacer balls 230, the connecting balls 213 and 223 can still be connected to the original first connecting pads 216 and the second connecting pads 226 respectively. Therefore it is advantageous for the first substrate 211 and the second substrate 221 to form more traces.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

1. A method for stacking BGA packages, comprising:
providing a first BGA package including a first substrate, a first chip, a first encapsulation and a plurality of first connecting balls, the first substrate having a first upper surface, a first bottom surface and a plurality of first connecting pads on the first upper surface, the first chip being disposed on the first upper surface of the first substrate, and the first connecting balls being disposed on the first connecting pads, the first encapsulation encapsulating the first chip;
providing a second BGA package including a second substrate, a second chip and a plurality of second connecting balls, the second substrate having a second upper surface, a second bottom surface and a plurality of second connecting pads on the second bottom surface, the second connecting balls being disposed on the connecting pads;
stacking the second BGA package and the first BGA package so that the second connecting balls of the second BGA package contact the first connecting balls of the first BGA package correspondingly; and
reflowing the first connecting balls and the second connecting balls contacting each other correspondingly to melt them to form a plurality of spacer balls, wherein the spacer balls connect the first connecting pads of the first BGA package and the second connecting pads of the second BGA package, and a height of the first encapsulation is smaller than that of the spacer balls.

2. The method for stacking BGA packages according to claim 1, wherein the first connecting balls have the same dimension as the second connecting balls.

3. The method for stacking BGA packages according to claim 2, wherein the height of the first connecting balls is in a range of 0.28˜0.35 mm, and the height of the second connecting balls is in a range of 0.28˜0.35 mm.

4. The method for stacking BGA packages according to claim 1, wherein a plurality of solder balls are disposed on the first bottom surface of the first substrate.

5. The method for stacking BGA packages according to claim 1, wherein the height of spacer balls is in a range of 0.35˜0.5 mm.

6. The method for stacking BGA packages according to claim 1, wherein the height of the spacer balls is 0.38 mm.

7. The method for stacking BGA packages according to claim 1, wherein the space between the spacer balls is 0.65 mm.

8-10. (canceled)

11. The method for stacking BGA packages according to claim 1, wherein the second chip of the second BGA package is disposed on the second upper surface of the second substrate.

12. The method for stacking BGA packages according to claim 11, wherein the second BGA comprises a second encapsulation which is formed on the second upper surface of the second substrate to encapsulate the second chip.

13. The method for stacking BGA packages according to claim 1, wherein the first connecting pads are formed around the upper surface of the first substrate, and the second connecting pads are formed around the bottom surface of the second substrate.
